(19) United States
(12) Patent Application Publication
(10) Pub. No.: US 2009/0086453 A1
(43) Pub. Date: Apr. 2, 2009

(54) Package with passive component support assembly

(75) Inventor: Jitesh Shah, Fremont, CA (US)

Correspondence Address: Roeder & Broder LLP, 5560 Chelsea Avenue, La Jolla, CA, 92037, US

(73) Assignee: Integrated Device Technology, Inc.

(21) Appl. No.: 11/904,997

(22) Filed: Sep. 28, 2007

(51) Int. Cl. H05K 7/02; H05K 1/16; H05K 3/20

(52) U.S. Cl. 361/782; 29/831; 361/760

(57) ABSTRACT

A package (16) for electrically connecting one or more integrated circuits (12) to a printed circuit board (14) includes a substrate body (16A), a pinout (16B), and a support assembly (18). The substrate body (16A) includes at least one insulating layer (222), and at least one patterned conductive layer (220) that is electrically connected to the integrated circuit (12) and the printed circuit board (14). The pinout (16B) extends between the substrate body (16A) and the printed circuit board (14), and the pinout (16B) electrically and mechanically connects the substrate body (16A) to the printed circuit board (14). The support assembly (18) includes at least one support (38) that extends between the substrate body (16A) and the printed circuit board (14) to support the substrate body (16A) relative to the printed circuit board (14). The support (38) includes a passive electrical component (19) that is electrically connected to the at least one patterned conductive layer (220). As a result thereof, the support (38) inhibits thermal and/or mechanical shock and cycles from causing mechanical instability an interface of the package (16) and the printed circuit board (14). Further, because the passive electrical components (19) are integrated into the support (38), valuable space in the printed circuit board (16A) is saved.

### BACKGROUND

Digital systems often include one or more integrated circuits (also referred to as “chips”) that are coupled to a printed circuit board, using one or more packages. The package includes a plurality of power conductors, a plurality of ground conductors, and a plurality of passive electrical components such as decoupling capacitors and resistors. Additionally, the package includes a pinout that mechanically and electrically connects the package to the printed circuit board.

Recently, to scale device functionality, two or more chips have been secured to a single package in a larger package with the same pinout as the original package. This design provides twice the memory capacity or more (depending upon the number of chips) in the new multi-chip package with the same pinout size as a single chip package. This typically leads to a large package body to adequately route all the functions of the chips with the small pinout footprint. Accordingly, a relatively large portion of package body will cantilever away from the pinout. This can cause mechanical instability due to the large cantilevering portion of the package body over the pinout. As a result thereof, thermal and/or mechanical shock and cycles in the multi-chip package can cause mechanical instability at the multi-chip package and the printed circuit board interface.

### SUMMARY

The present invention is directed toward a package for electrically connecting an integrated circuit to a printed circuit board. The package includes a substrate body, a pinout, and a support assembly. The substrate body includes at least one insulating layer, and at least one patterned conductive layer that is electrically connected to the integrated circuit and the printed circuit board. The pinout extends between the substrate body and the printed circuit board, and the pinout electrically and mechanically connects the substrate body to the printed circuit board. The support assembly includes at least one support that extends between the substrate body and the printed circuit board to support the substrate body relative to the printed circuit board.

In certain embodiments, the support includes a passive electrical component that is electrically connected at each end to one or more patterned conductive layers. As a result thereof, the support inhibits thermal and/or mechanical shock and cycles from causing mechanical instability in the substrate body. Further, because passive electrical components are integrated underneath the substrate cantilever overhang, valuable real estate on printed circuit board is saved.

In one embodiment, the passive electrical component is a capacitor. Additionally, the support can include a ground pad and a power pad that are electrically connected to the capacitor.

As provided herein, the support assembly can include a plurality of spaced apart supports. Further, these supports can be positioned near a perimeter of the substrate body, and the supports can cooperate to encircle the pinout.

In another embodiment, the passive electrical component is a resistor.

Additionally, the support assembly can be electrically and mechanically connected to both the substrate body and the printed circuit board. As a result thereof, the support assembly provides good support for the substrate body.

In alternative, additional embodiments, the present invention is also directed to a multi-chip package, a digital system, and a method for making a package.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a simplified side view of a digital system including a package having features of the present invention;

FIG. 2 is an enlarged, cut-away view of a portion the package taken from line 2-2 in FIG. 1;

FIG. 3 is a simplified bottom view of the package of FIG. 1;

FIG. 4 is an enlarged, simplified perspective view of a portion of the package of FIG. 1;

FIG. 5 is a simplified side view of another embodiment of the digital system and the package; and

FIG. 6 is an enlarged, simplified perspective view of a portion of the package of FIG. 5.

### DESCRIPTION

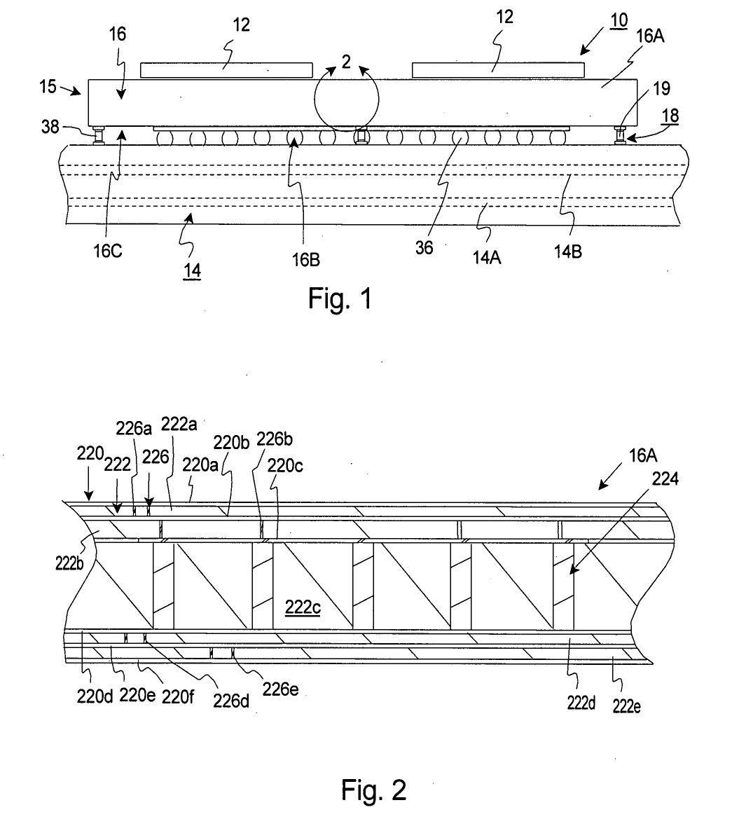

FIG. 1 is a simplified side view of a portion of a digital system 10 that includes a plurality of integrated circuits 12 (“chips”), a printed circuit board 14, and a package 16 that attaches and electrically connects the integrated circuits 12 to the printed circuit board 14. The design of each of these components can vary pursuant to the teachings provided herein. In FIG. 1, the integrated circuits 12 and the package 16 cooperate to form a multi-chip package 15 having twice the memory capacity or more, depending upon the number of chips 12.

As an overview, the package 16 includes a support assembly 18 that mechanically supports the package 16. As a result thereof, thermal and/or mechanical shock and cycles in the multi-chip package 15 are inhibited from causing mechanical instability at the multi-chip package and at an interface of the package 16 and the printed circuit board interface 14. In certain embodiments, the support assembly 18 includes one or more passive electrical components 19 are that integrated into the support assembly 18. This saves valuable space on the printed circuit board 16.

Each integrated circuit 12 consists of a number of circuit elements positioned on a chip of silicon crystal or other semiconductor material. The design of each integrated circuit 12 can vary. For example, each integrated circuit 12 can be a flip type chip as illustrated in FIG. 1, or a wire bond type chip. The number of integrated circuits 12 positioned on the package 16 can vary. In FIG. 1, two integrated circuits 12 are electrically and mechanically directly connected to the single package 16. Alternatively, more than two integrated circuits 12 can be positioned on the single package 16 The printed circuit board 14 includes a flat board that is made of non-conducting material and a plurality of predefined conductive metal pathways that are printed on the surface of the board. In one embodiment, the printed circuit board 14 also includes power rail 14A (illustrated in phantom) and a ground rail 14B (illustrated in phantom).

The package 16 electrically and mechanically connects the plurality of integrated circuits 12 to the printed circuit board 14. In certain embodiments, the package 16 also fixedly secures the integrated circuits 12 to the printed circuit board 14 and provides mechanical support to the integrated circuits 12. The design of the package 16 can vary. For example, in FIG. 1, the package 16 is designed to electrically connect two flip type chips 12 to the printed circuit board 14. Alternatively, the package 16 could be designed to electrically connect one or more wire bond type chips to the printed circuit board 14.

The package 16 includes a substrate body 16A and a pinout 16B, in addition to the support assembly 18. In FIG. 1, with the multi-chip package 15, the package body 16A needs to be relatively large to adequately route all the functions of the chips 12 with the pinout 16B that has a relatively small footprint. As a result thereof, a relatively large cantilevering portion 16C of the substrate body 16A will cantilever away from the pinout 16B. In one non-exclusive embodiment, (i) the substrate body 16A has a width (across the Page) of approximately 35 mm and a length (into the page) of approximately 35 mm, and (ii) the pinout 16B has a width (across the Page) of approximately 28 mm and a length (into the page) of approximately 28 mm.

FIG. 2 is an enlarged, simplified cut-away view of a portion of one, non-exclusive embodiment of the substrate body 16A. In one embodiment, the substrate body 16A includes a plurality of spaced apart patterned conductive layers 220, a plurality of spaced apart insulating layers 222, a plurality of core vias 224 (only a few are illustrated in FIG. 2), and a plurality of micro-vias 226 (only a few are illustrated in FIG. 2). The design and number of each of these components can be varied to achieve the design requirements of the package 16 (illustrated in FIG. 1).

In this embodiment, the substrate body 16A includes six spaced apart patterned conductive layers 220. These conductive layers 220 can be labeled from top to bottom as the first conductive layer 220a, the second conductive layer 220b, the third conductive layer 220c, the fourth conductive layer 220d, the fifth conductive layer 220e, and the sixth conductive layer 220f. Alternatively, the package 16 could be designed to have more than six or fewer than six spaced apart patterned conductive layers 220. The conductive material used in the conductive layers 220 can vary. A suitable conductive material is copper.

The first conductive layer 220a can include a plurality of mount pads (not shown) that are used to electrically and mechanically connect the integrated circuits 12 (illustrated in FIG. 1) to the substrate body 16A. Somewhat similarly, the sixth conductive layer 220f can include a plurality of mount pads (not shown) that are used to electrically and mechanically connect the substrate body 16A to the pinouts 16B (illustrated in FIG. 1).

It should be noted that the use of the terms “first”, “second”, “third”, etc., with regard to the conductive layers is for the sake of convenience and ease in understanding the invention only and are not intended to be limiting in any manner. In other words, any of the conductive layers 220 can be the “first conductive layer”, the “second conductive layer”, or the “third conductive layer”, etc.

The insulating layers 222 mechanically and electrically separate the conductive layers 220. The number of insulating layers 222 will depend upon the number of conductive layers 220. In FIG. 2, the insulating layers 222 can be labeled from top to bottom as the first insulating layer 222a, the second insulating layer 222b, the third insulating layer 222c (also referred to as the “core layer”), the fourth insulating layer 222d, and the fifth insulating layer 222e. In this embodiment, (i) the first insulating layer 222a separates and isolates the first and second conductive layers 220a, 220b, (ii) the second insulating layer 222b separates and isolates the second and third conductive layers 220b, 220c, (iii) the core 222c separates and isolates the third and fourth conductive layers 220c, 220d, (iv) the fourth insulating layer 222d separates and isolates the fourth and fifth conductive layers 220d, 220e, and (v) the fifth insulating layer 222e separates and isolates the fifth and sixth conductive layers 220e, 220f.

The insulating material used in the insulating layers 222 can vary. Suitable materials for the insulating material include dielectrics, such as glass epoxy.

It should be noted that the use of the terms “first”, “second”, “third”, etc., with regard to the insulating layers is for the sake of convenience and ease in understanding the invention only and are not intended to be limiting in any manner. In other words, any of the insulating layers 220 can be the “first insulating layer”, the “second insulating layer”, or the “third insulating layer”, etc.

The vias 224, 226 are formed in the insulating layers 222 and can electrically connect any two patterned conductive layers 220. The vias 224, 226 electrically connect the conductive layers 220 to the power rail 14A and the ground rail 14B on the circuit board 14.

The plurality of core vias 224 are electrically conductive paths that extend through the core layer 222c and that electrically connect the fourth conductive layer 220d to the third conductive layer 220c. The number and location of the core vias 224 can vary. In FIG. 2, only five core vias 224 are illustrated. A suitable conductive material for the core vias 224 is copper.

The plurality of micro-vias 226 are electrically conductive paths that extend through one or more of the conductive layers 220 and that electrically connect the two conductive layers 220. The number and location of the micro-vias 226 can vary. In FIG. 2, (i) two first micro-vias 226a that extend through the first insulating layer 222a are illustrated, (ii) two second micro-vias 226b that extend through the second insulating layer 222b are illustrated, (iii) two fourth micro-vias 226d that extend through the fourth insulating layer 222d are illustrated, and (i) two fifth micro-vias 226e that extend through the fifth insulating layer 222d are illustrated for reference. Suitable conductive materials for the micro-vias 226 include copper.

Referring back to FIG. 1, the pinout 16B electrically and mechanically connects the substrate body 16A to the printed circuit board 14. In this embodiment, the pinout 16B for the multi-chip package 15 is approximately the same size as the pinout 16B for a single chip package 15. In one non-exclusive example, the pinout 16B can include a ball grid array (BGA) that electrically and mechanically couples the package 16 to the printed circuit board 14. For example, the pinout 16B can include a plurality of pins 36. In one non-exclusive embodiment, the pins 36 are solder balls. Further, the pins 36 can include ground pins, power pins and/or signal pins. These pins 36 can be strategically arranged to reduce crosstalk and/or to improve signal timing margins.

The support assembly 18 supports the cantilevering portion 16C of the substrate body 16A so that thermal and/or mechanical shock and cycles in the multi-chip package 15 are inhibited from causing mechanical instability at an interface between the multi-chip package 15 and the printed circuit board 14. In FIG. 1, the support assembly 18 includes one or more spaced apart supports 38 that are positioned and extend between the cantilevering portion 16C of the substrate body 16A and the printed circuit board 14 to support the cantilevering portion 16C relative to the printed circuit board 14. With this design, a stiffener ring (not shown) or other mechanical structure (not shown) is not needed to provide support to the cantilevering portion 16C.

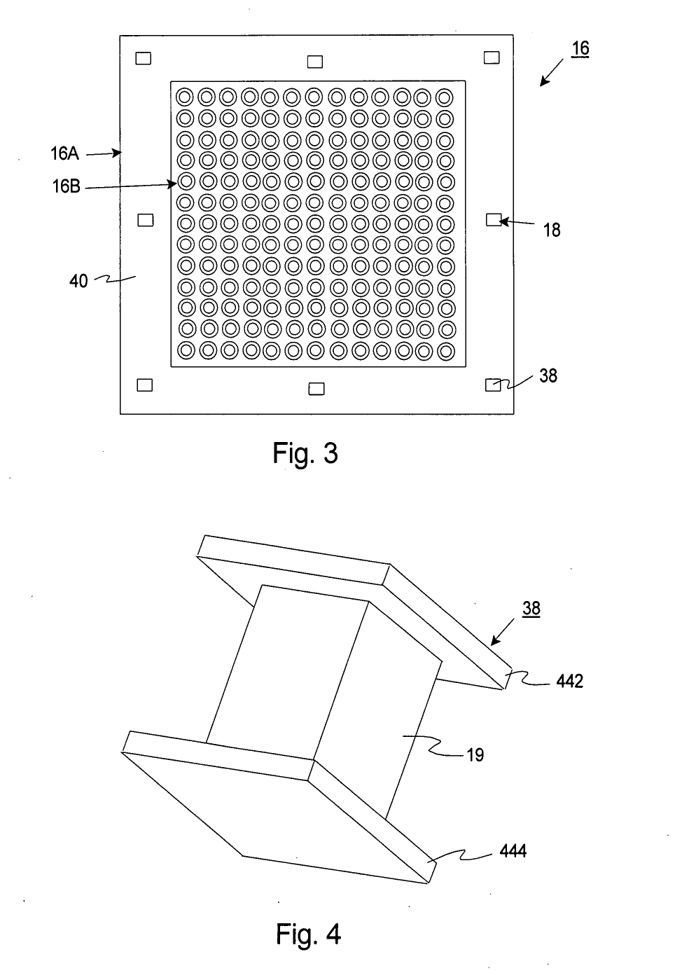

The number and design of the supports 38 can vary. FIG. 3 is a simplified bottom view of the package 16 of FIG. 1. In this embodiment, the support assembly 18 includes eight supports 38 that are positioned near a perimeter 40 of the substrate body 16A and that arranged around the pinout 16B. Alternatively, the support assembly 18 can be designed with more than eight, or fewer than eight supports 38.

FIG. 4 is an enlarged, simplified perspective view of one of the supports 38. In this embodiment, the support 38 includes the passive electrical component 19 that is integrated into the support 38. A power pad 442 and a ground pad 444 are also illustrated in FIG. 4. In FIG. 4, the passive electrical component 19, the power pad 442 and the ground pad 444 each have a generally rectangular cross-sectional shape. Alternatively, one or all of these components can have a different configuration, such as circular, oval, or octagonal cross-sectional shape.

In this embodiment, the power pad 442 is a metal pad etched on the substrate body 16, the power pad 442 is directly mechanically connected to the substrate body 16 (illustrated in FIG. 2), and the power pad 442 is electrically connected to one of the conductive layers 220 (illustrated in FIG. 2) in the substrate body 16. Moreover, the power pad 442 is mechanically and electrically connected to the passive electrical component 19.

Somewhat similarly, the ground pad 444 is a metal pad etched in the printed circuit board 14, the ground pad 444 is directly mechanically connected to the printed circuit board 14 (illustrated in FIG. 1), and the ground pad 444 is electrically connected to the ground rail 14B (illustrated in FIG. 1) in the printed circuit board 14. Further, the ground pad 444 is mechanically and electrically connected to the passive electrical component 19.

Alternatively, the power pad 442 can be etched onto the printed circuit board 14 and the ground pad 444 can be etched onto the substrate body 16.

The passive electrical component 19 can be any active or passive electrical component. For example, the passive electrical component 19 can be one or more decoupling capacitors, termination resistors, or integrated circuits. As used herein, the term passive electrical component 19 does not include interconnects, such as solder balls.

The decoupling capacitors are electrically connected to the conductive layers 220 (illustrated in FIG. 2). With this design, the capacitors help to stabilize the voltage delivered to the integrated circuits 12 (illustrated in FIG. 1). For example, when there is a sudden change in the current drawn by the integrated circuits 12, the decoupling capacitors provide a local source of charge so that the current can be supplied quickly without causing the voltage across the power and ground nodes to dip suddenly. Inadequate decoupling leads to excessive power supply noise causing signal integrity and EMC problems, and ultimately adversely influencing the reliability of the product. Further, the impedance path for the capacitors positioned adjacent the substrate body 16A is relatively short and is useful to supply charge during very high frequency current transients.

With this design, the supports 38 not only provide mechanical support but also help in minimizing noise across the power-ground rails during large switching events for the circuits 12. Stated in another fashion, electrical performance and structural support can be achieved while saving valuable space in the printed circuit board. Further, this placement of the capacitors allows for use of a relatively large number of discrete capacitors without taking up valuable space and without taking up routing space.

Further, the high-frequency power does not have to come in from the swiss-cheesed planes due to signal vias. Since the capacitors are located at the periphery before the signal pins, the power to these capacitors and ultimately to the chips 12 is brought in through solid power-ground planes.

In one embodiment, each of the discrete capacitors is a premade, low inductance capacitor. For example, suitable capacitors include surface mounted, low inductance capacitors sold by AVX, having a sales office in Santa Clara, Calif.

Alternatively, other types of passive electrical components 19 can be used in one or more of the supports 38. For example, the passive electrical component 19 can include one or more resisters, such as termination resistors.

Referring back to FIG. 1, one assembly process for attaching the package 16 includes attaching the supports 38 on the solder ball side of the substrate body 16A using solder paste screening and reflow. This step will typically be followed after solder ball attach process. The size of the supports 38 has to be smaller than the stand-off height of the pins 36 after the pins 36 are attached.

The second level assembly process (assembling the package 15 on to the printed circuit board 14) steps would be a typical board assembly process. The only exception would be the volume of solder paste required to maintain good contact between the supports 38 and the corresponding pad on the printed circuit board 14. In order to account for a slight collapse in the pin 36 stand-off height, the supports 38 will require a larger volume of paste to be deposited on the printed circuit board 14 pad.

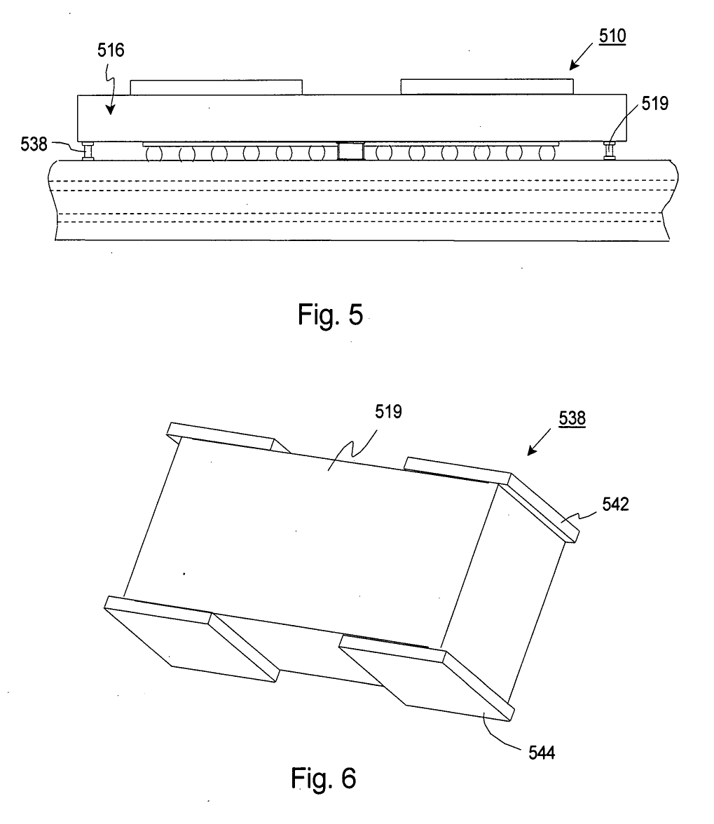

FIG. 5 is a simplified side view of another embodiment of the digital system 510, the package 516, and the support 538; and FIG. 6 is an enlarged, simplified perspective view of the support 538. In this embodiment, the digital system 510, the package 516, and the support 538 are somewhat similar to the corresponding components described above. However, in this embodiment, the passive electrical component 519 of each support 538 is slightly bigger. Further, this design includes pair of spaced apart power pads 542 etched into the substrate body (not shown) and a pair of spaced apart ground pads 544 etched into to the printed circuit board (not shown).

While the particular invention as herein shown and disclosed in detail are fully capable of obtaining the objects and providing the advantages herein before stated, it is to be understood that they are merely illustrative of one or more embodiments and that no limitations are intended to the details of construction or design herein shown other than as described in the appended claims.

What is claimed is:

1. A package for electrically connecting an integrated circuit to a printed circuit board, the package comprising:
a substrate body that includes at least one insulating layer and at least one patterned conductive layer;
a pinout that is adapted to extend between the substrate body and the printed circuit board, the pinout being adapted to electrically and mechanically connect the substrate body to the printed circuit board; and
a support assembly-that includes at least one support that is adapted to extend between the substrate body and the printed circuit board to support the substrate body relative to the printed circuit board, the support including a passive electrical component that is electrically connected to the at least one patterned conductive layer.

2. The package of claim 1 wherein the passive electrical component is a capacitor.

3. The package of claim 2 wherein the support includes a ground pad and a power pad that are electrically connected to the capacitor.

4. The package of claim 1 wherein the support assembly includes a plurality of spaced apart supports.

5. The package of claim 4 wherein the supports are positioned near a perimeter of the substrate body, and the supports cooperate to encircle the pinout.

6. The package of claim 1 wherein the passive electrical component is a resistor.

7. The package of claim 1 wherein the support assembly is electrically and mechanically connected to the substrate body, and the support assembly is adapted to be electrically and mechanically connected to the printed circuit board.

8. A multi-chip package comprising the package of claim 1 and at least two integrated circuits that are mechanically and electrically connected to the package.

9. A digital system comprising a printed circuit board, and the multi-chip package of claim 8 that is electrically and mechanically connected to the printed circuit board.

10. A package for electrically connecting a pair of integrated circuits to a printed circuit board, the package comprising:
a substrate body that includes at least one insulating layer, at least one patterned conductive layer, and a perimeter;
a pinout that is adapted to extend between the substrate body and the printed circuit board, the pinout being adapted to electrically and mechanically connect the substrate body to the printed circuit board; and
a support assembly that includes a plurality of spaced apart supports that are adapted to extend between the substrate body and the printed circuit board to support the substrate body relative to the printed circuit board, wherein each support including a passive electrical component that is electrically connected to the at least one patterned conductive layer;
wherein the supports are positioned near a perimeter of the substrate body, and the supports cooperate to encircle the pinout; and wherein the supports are electrically and mechanically connected to the substrate body, and the support assembly is adapted to be electrically and mechanically connected to the printed circuit board.

11. The package of claim 10 wherein the passive electrical component is a capacitor.

12. The package of claim 11 wherein each support includes a ground pad and a power pad that are electrically connected to the capacitor.

13. The package of claim 10 wherein the passive electrical component is a resistor.

14. A multi-chip package comprising the package of claim 10 and at least two integrated circuits that are mechanically and electrically connected to the package.

15. A digital system comprising a printed circuit board, and the multi-chip package of claim 14 that is electrically and mechanically connected to the printed circuit board.

16. A method for making a package for electrically connecting an integrated circuit to a printed circuit board, the method comprising the steps of:
providing a substrate body that includes at least one insulating layer and at least one patterned conductive layer;
mechanically and electrically connecting the substrate body and the printed circuit board with a pinout that extends between the substrate body and the printed circuit board; and
supporting the substrate body relative to the printed circuit board with at least one support that extends between the substrate body and the printed circuit board, the support including a passive electrical component that is electrically connected to the at least one patterned conductive layer.

17. The method of claim 16 wherein the passive electrical component is a capacitor.

18. The method of claim 16 wherein the step of supporting includes supporting with a plurality of spaced apart supports that are positioned near a perimeter of the substrate body, and the supports cooperate to encircle the pinout.

19. The method of claim 16 wherein the passive electrical component is a resistor.

20. The method of claim 16 wherein the step of supporting includes electrically and mechanically connecting the support to the substrate body and the printed circuit board.
